(19) United States
(12) Patent Application Publication
(10) Pub. No.: US 2026/0020158 A1
(43) Pub. Date: Jan. 15, 2026

(54) METHOD OF USING OPTIMIZED PITCH FOR INSTALLING PROCESSING CIRCUIT AT PRINTED CIRCUIT BOARD, AND ASSOCIATED APPARATUS

(71) Applicant: Realtek Semiconductor Corp., HsinChu (TW)

(72) Inventors: Chao-Min Lai, HsinChu (TW); Shou-Te Yen, HsinChu (TW); Yu-Jen Lin, HsinChu (TW); Ping-Chia Wang, HsinChu (TW)

(73) Assignee: Realtek Semiconductor Corp., HsinChu (TW)

(21) Appl. No.: 19/008,590

(22) Filed: Jan. 2, 2025

(30) Foreign Application Priority Data
Jul. 11, 2024 (TW) 113125967

(51) Int. Cl. H05K 1/18; H01L 23/498; H05K 1/11

(52) U.S. Cl. CPC H05K 1/181; H01L 23/49816; H01L 23/49838; H05K 1/111; H05K 2201/10734

(57) ABSTRACT

A method of using optimized pitch for installing a processing circuit at a printed circuit board (PCB) and associated apparatus are provided. The method may include: providing a set of first terminals on a predetermined surface of a package of the processing circuit, the set of first terminals corresponding to a set of first pads within a first sub-region of a predetermined installation region of the PCB, where a first pitch of the set of first terminals along a predetermined direction is equal to a first predetermined value; and providing a set of second terminals on the predetermined surface of the package of the processing circuit, the set of second terminals corresponding to a set of second pads within a second sub-region of the predetermined installation region, where a second pitch of the set of second terminals along the predetermined direction is equal to a second predetermined value.

### BACKGROUND OF THE INVENTION

### 1. Field of the Invention

The present invention is related to circuit design, and more particularly, to a method of using optimized pitch for installing a processing circuit at a printed circuit board (PCB) and associated apparatus such as the processing circuit and the PCB.

### 2. Description of the Prior Art

According to the related art, a memory package complying with low-power double data rate (LPDDR) standards such as the LPDDR5/LPDDR5X standards may be coupled to a PCB through 15 columns×21 rows of solder balls (or “balls”) in a certain configuration, with the ball pitch thereof such as the pitch along the X-axis and the pitch along the Y-axis being equal to 0.8 millimeters (mm) and 0.7 mm, respectively. For example, when the ball pitch of a package of a system-on-chip (SoC) along the X-axis and the Y-axis is equal to 0.65 mm, if a large number of vias are arranged in an SoC installation region on the PCB, it is difficult to route traces between these vias. Assuming that the ball pitch of the SoC package is increased to be the same as a certain ball pitch of the memory package, the package area of the SoC will be greatly increased. Thus, a novel method and associated architecture are needed for solving these problems in a way that is less likely to introduce a side effect.

### SUMMARY OF THE INVENTION

It is an objective of the present invention to provide a method of using optimized pitch for installing a processing circuit at a PCB and associated apparatus such as the processing circuit and the PCB, in order to solve the problems in the related art.

At least one embodiment of the present invention provides a method of using optimized pitch for installing a processing circuit at a PCB, where the PCB has a predetermined installation region for installing the processing circuit. The method may comprise: providing a set of first terminals on a predetermined surface of a package of the processing circuit, the set of first terminals corresponding to a set of first pads within a first sub-region of the predetermined installation region, wherein a first pitch of the set of first terminals along a predetermined direction on the predetermined surface is equal to a first predetermined value; and providing a set of second terminals on the predetermined surface of the package of the processing circuit, the set of second terminals corresponding to a set of second pads within a second sub-region of the predetermined installation region, wherein a second pitch of the set of second terminals along the predetermined direction on the predetermined surface is equal to a second predetermined value, and the second predetermined value is not equal to the first predetermined value. For example, the PCB may be arranged to install the processing circuit and a random access memory. More particularly, in a three-dimensional (3D) space corresponding to an X-axis, a Y-axis and a Z-axis that are orthogonal to each other, in a situation where a normal vector of the predetermined installation region is parallel to the Z-axis and the processing circuit and the random access memory are arranged along a direction of the X-axis on the PCB, the predetermined direction may represent a direction of any axis among the X-axis and the Y-axis.

At least one embodiment of the present invention provides a processing circuit whose package is implemented according to the above method, where the package of the processing circuit may comprise: the set of first terminals, positioned in a first sub-region of a terminal region on the predetermined surface, wherein the first sub-region of the terminal region and the first sub-region of the predetermined installation region correspond to each other; and the set of second terminals, positioned in a second sub-region of the terminal region on the predetermined surface, wherein the second sub-region of the terminal region and the second sub-region of the predetermined installation region correspond to each other.

At least one embodiment of the present invention provides a PCB whose multiple pads such as soldering pads are implemented according to the above method, where the multiple pads of the PCB may comprise: the set of first pads, positioned in the first sub-region of the predetermined installation region; and the set of second pads, positioned in the second sub-region of the predetermined installation region.

It is an advantage of the present invention that, through proper design, the method, the processing circuit and the PCB of the present invention can achieve package area minimization of the processing circuit without significantly increasing the associated costs such as the material costs (e.g., the PCB costs). For example, the processing circuit can be an SoC, the PCB can be arranged to install the processing circuit such as the SoC and the random access memory such as an LPDDR fifth generation or above (LPDDR 5 or above) random access memory, and the above-mentioned optimized pitch can represent the optimized SoC ball pitch for LPDDR5 designs (e.g., the LPDDR5/5X designs). In addition, the method, the processing circuit and the PCB of the present invention can solve the problems in the related art in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an electronic device according to an embodiment of the present invention, where the electronic device is implemented based on a method of using optimized pitch for installing a processing circuit at a PCB in the present invention.

FIG. 2 illustrates a circuit architecture control scheme of the method according to an embodiment of the present invention.

FIG. 3 illustrates a first layer involved with the circuit architecture control scheme shown in FIG. 2.

FIG. 4 illustrates a third layer involved with the circuit architecture control scheme shown in FIG. 2.

FIG. 5 illustrates a fifth layer involved with the circuit architecture control scheme shown in FIG. 2.

FIG. 6 illustrates some pitches involved with the circuit architecture control scheme shown in FIG. 2 according to an embodiment of the present invention.

FIG. 7A illustrates some terminals involved with the circuit architecture control scheme shown in FIG. 2 according to an embodiment of the present invention.

FIG. 7B illustrates the associated pitches of the terminals shown in FIG. 7A.

FIG. 8 illustrates a flowchart of the method according to an embodiment of the present invention.

### DETAILED DESCRIPTION

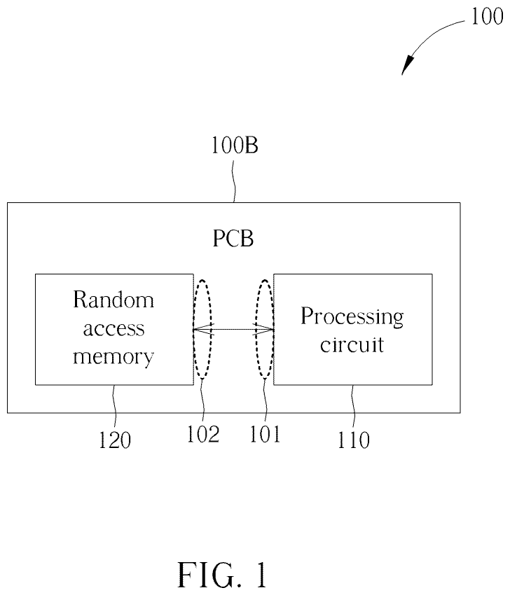

FIG. 1 is a schematic diagram of an electronic device 100 according to an embodiment of the present invention, where the electronic device 100 is implemented based on a method of using optimized pitch for installing a processing circuit (e.g., the processing circuit 110) at a PCB (e.g., the PCB 100B) in the present invention. As shown in FIG. 1, the electronic device 100 may comprise a processing circuit 110, a random access memory 120, and a PCB 100B for installing or mounting the processing circuit 110 and the random access memory 120. The processing circuit 110 may control operations of the electronic device 100, and the random access memory 120 may store information for the electronic device 100 (or the processing circuit 110). In addition, the PCB 100B may comprise a plurality of pads, such as multiple pads 101 for coupling the processing circuit 110 to the PCB 100B and multiple pads 102 for coupling the random access memory 120 to the PCB 100B. Multiple terminals of the processing circuit 110 may be connected to the multiple pads 101, respectively, and multiple terminals of the random access memory 120 may be connected to the multiple pads 102, respectively. The processing circuit 110 and the random access memory 120 may be coupled to each other through the PCB 100B, at least one portion of pads (e.g., a portion of pads or all pads) among the multiple pads 101, and at least one portion of pads (e.g., a portion of pads or all pads) among the multiple pads 102. Examples of the electronic device 100 may include, but are not limited to: a portable electronic device, a multifunctional mobile phone and a wearable device. Examples of the processing circuit 110 may include, but are not limited to: an application processor (AP) and a central processing unit (CPU).

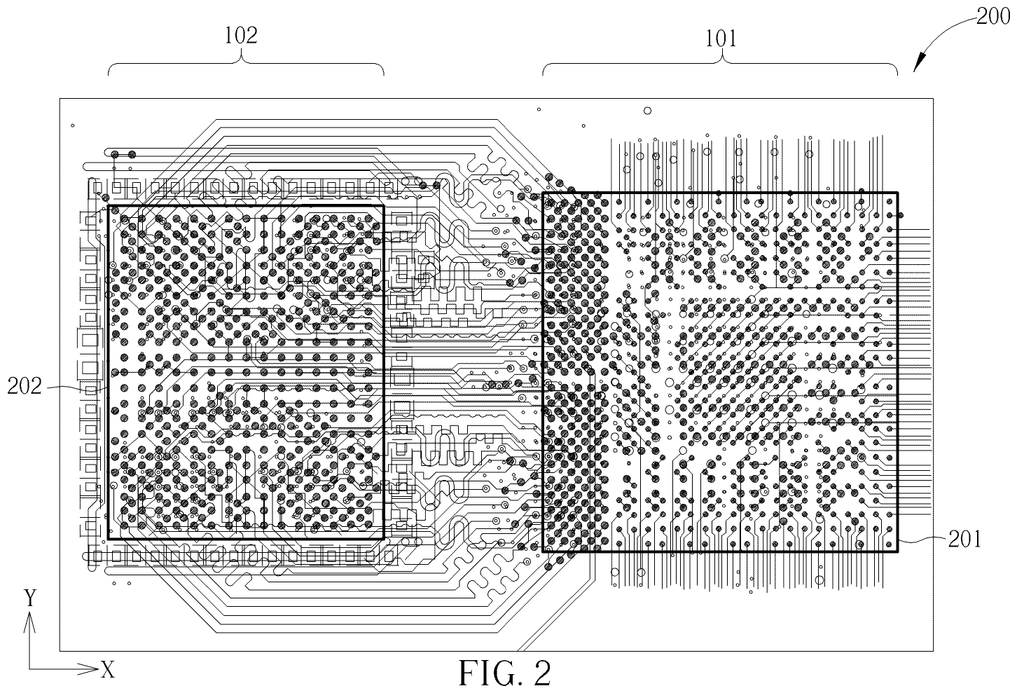

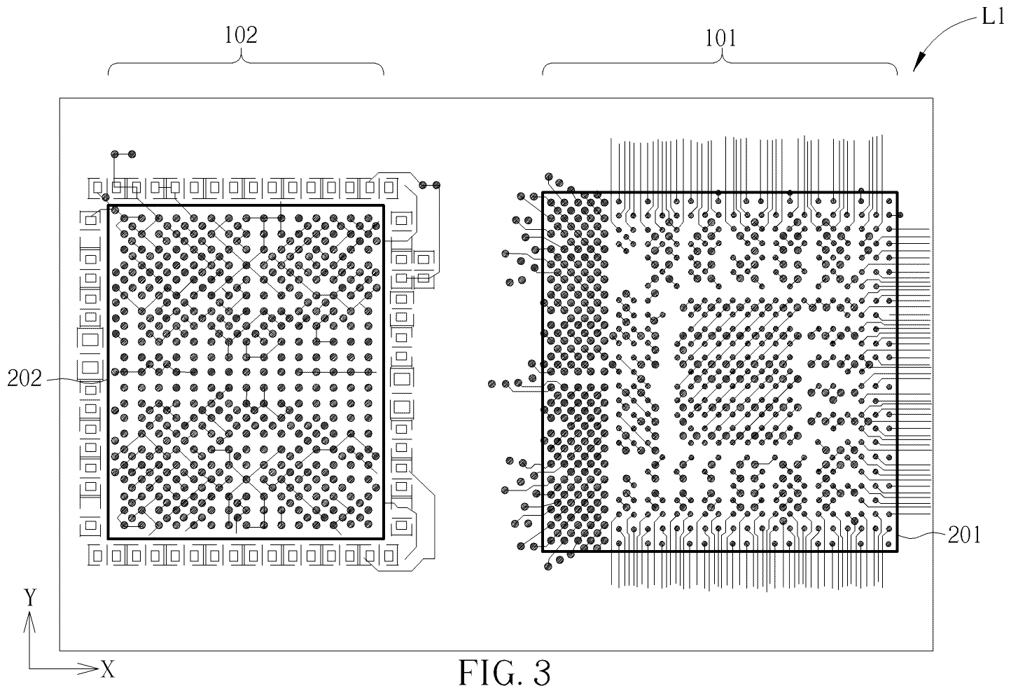

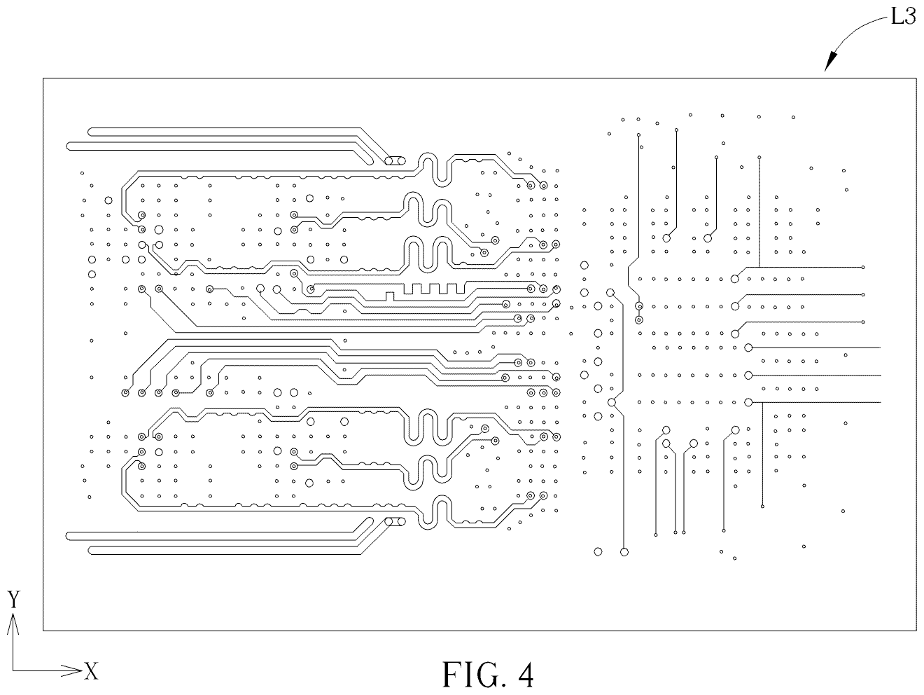

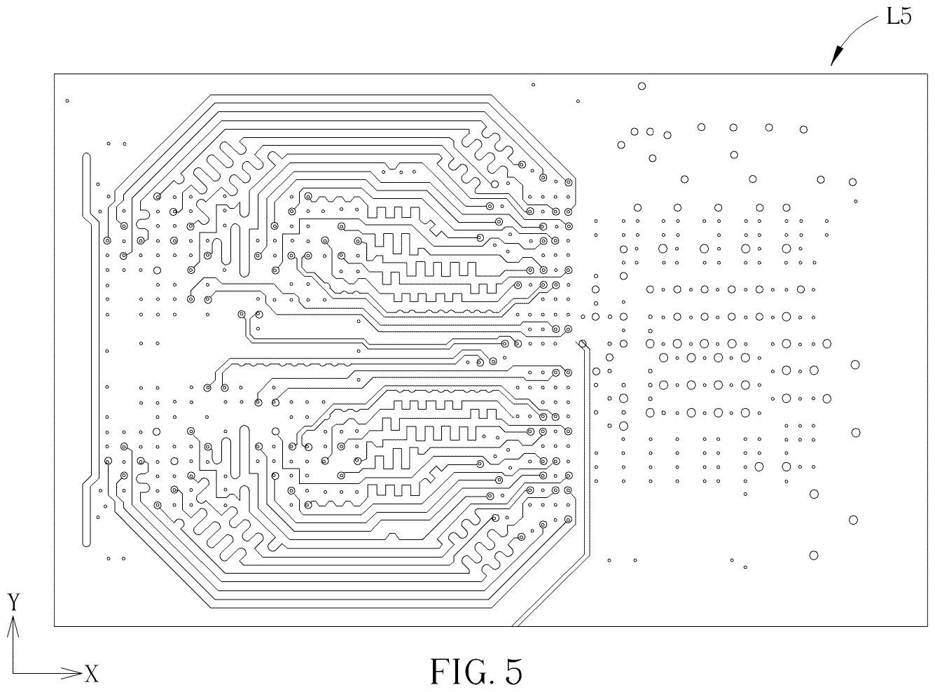

FIG. 2 illustrates a circuit architecture control scheme of the method according to an embodiment of the present invention, and FIG. 3, FIG. 4 and FIG. 5 illustrate a first layer, a third layer and a fifth layer, such as three layers L1, L3 and L5 among five layers of circuits (or “the five-layer circuit”), involved with the circuit architecture control scheme shown in FIG. 2, respectively, where the remaining two layers (i.e., the second layer and the fourth layer) within the five-layer circuit may be arranged to isolate the above-mentioned three layers L1, L3 and L5, and may be regarded as isolation layers. The PCB 100B may comprise the circuit structure 200 shown in FIG. 2, and the circuit structure 200 may comprise the above-mentioned five-layer circuit, and more particularly, the above-mentioned three layers L1, L3 and L5. According to some embodiments, the circuit architecture 200 may comprise more layers of circuits.

For example, the PCB 100B may have a predetermined installation region 201 (e.g., an SoC installation region) for installing/mounting the processing circuit 110 (e.g., an SoC) as shown in the right half part of FIG. 3, and another predetermined installation region 202 (e.g., a memory installation region) for installing/mounting the random access memory 120 (e.g., an LPDDR5/5X random access memory) as shown in the left half part of FIG. 3, where the multiple pads 101 may be positioned within the predetermined installation region 201 (e.g., the SoC installation region) for coupling the processing circuit 110 (e.g., the SoC) to the PCB 100B, and the multiple pads 102 may be positioned within the predetermined installation region 202 (e.g., the memory installation region) for coupling the random access memory 120 (e.g., the LPDDR5/5X random access memory) to the PCB 100B. For better comprehension, the smaller rectangles outside the predetermined installation region 202 in the left half part of FIG. 3 may represent multiple other pads, and the associated boundaries surrounding these smaller rectangles may represent some other predetermined installation region on the PCB 100B for installing/mounting multiple other components (e.g., multiple resistors).

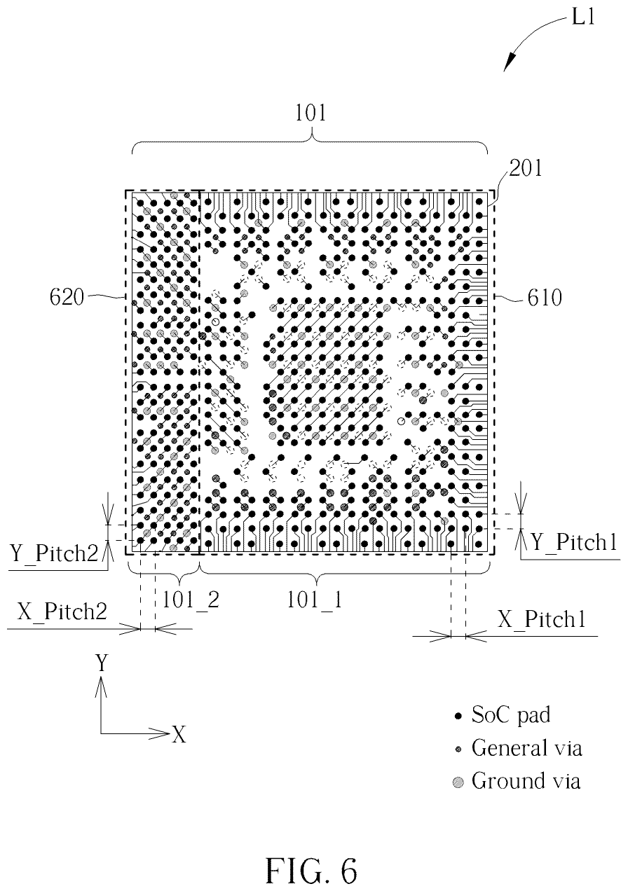

FIG. 6 illustrates some pitches involved with the circuit architecture control scheme shown in FIG. 2 according to an embodiment of the present invention. The processing circuit 110 may be implemented as the SoC, and the multiple pads 101 may also be referred to as multiple SoC pads 101. The predetermined installation region 201 such as the SoC installation region may comprise multiple sub-regions 610 and 620, and the multiple pads 101 may comprise multiple sets of pads 101_1 and 101_2 (or the SoC pads 101_1 and 101_2) positioned in the multiple sub-regions 610 and 620, respectively. For example, regarding the sub-region 610, the pitch X_Pitch1 of the set of pads 101_1 along the direction of the X-axis may be equal to a predetermined value such as 0.65 mm, and the pitch Y_Pitch1 of the set of pads 101_1 along the direction of the Y-axis may be equal to a predetermined value such as 0.65 mm, but the present invention is not limited thereto. In some examples, the pitch X_Pitch1 and/or the pitch Y_Pitch1 may vary. In addition, regarding the sub-region 620, the pitch X_Pitch2 of the set of pads 101_2 along the direction of the X-axis may be unequal to the pitch X_Pitch1, and the pitch Y_Pitch2 of the set of pads 101_2 along the direction of the Y-axis may be unequal to the pitch Y_Pitch1, to allow a layout space regarding at least one of a signal line and a via (e.g., a general via or a ground via) to be reserved between at least two adjacent pads among the set of pads 101_2, for coupling the processing circuit 110 to the random access memory 120 through the PCB 100B. For example, the pitch X_Pitch2 may be equal to a predetermined value such as 0.6 mm, and the pitch Y_Pitch2 may be equal to a predetermined value such as 0.7 mm, but the present invention is not limited thereto. In some examples, the pitch X_Pitch2 and/or the pitch Y_Pitch2 may vary.

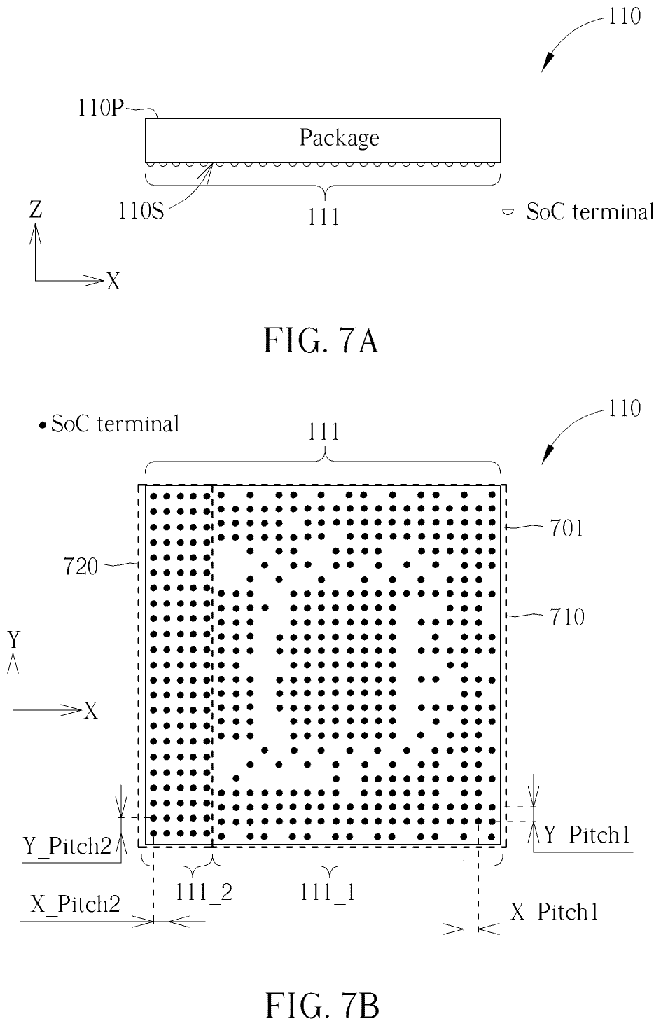

FIG. 7A illustrates some terminals involved with the circuit architecture control scheme shown in FIG. 2 according to an embodiment of the present invention, and FIG. 7B illustrates the associated pitches of the terminals shown in FIG. 7A. The processing circuit 110 may be implemented as the SoC, and the aforementioned multiple terminals of the processing circuit 110, such as the multiple terminals 111, may also be referred to as multiple SoC terminals 111. As shown in FIG. 7A, the multiple terminals 111 may be positioned on a predetermined surface 110S of a package 110P of the processing circuit 110, where the predetermined surface 110S may represent the surface (e.g., the bottom surface of the package 110P) that is closest to the PCB 100B when the processing circuit 110 is installed at/in the predetermined installation region 201 (e.g., the SoC installation region). In particular, the processing circuit 110 may have a terminal region 701 (not shown in FIG. 7A) positioned on the predetermined surface 110S, such as an entire region of the predetermined surface 110S. For better comprehension, assume that an observer may see the package 110P as a see-through package and the multiple terminals 111 at the bottom of the package 110P from above (or from the +Z-axis), but the present invention is not limited thereto.

As shown in FIG. 7B, the terminal region 701 may comprise multiple sub-regions 710 and 720, and the multiple terminals 111 may comprise multiple sets of terminals 111_1 and 111_2 (or the SoC terminals 111_1 and 111_2) positioned in the multiple sub-regions 710 and 720, respectively. For example, regarding the sub-region 710, the pitch X_Pitch1 of the set of terminals 111_1 along the direction of the X-axis may be equal to a predetermined value such as 0.65 mm, and the pitch Y_Pitch1 of the set of terminals 111_1 along the direction of the Y-axis may be equal to a predetermined value such as 0.65 mm, but the present invention is not limited thereto. In some examples, the pitch X_Pitch1 and/or the pitch Y_Pitch1 may vary. In addition, regarding the sub-region 720, the pitch X_Pitch2 of the set of terminals 111_2 along the direction of the X-axis may be unequal to the pitch X_Pitch1, and the pitch Y_Pitch2 of the set of terminals 111_2 along the direction of the Y-axis may be unequal to the pitch Y_Pitch1, to allow the layout space regarding the aforementioned at least one of the signal line and the via (e.g., the general via or the ground via) to be reserved between the aforementioned at least two adjacent pads among the set of pads 101_2 corresponding to the set of terminals 111_2, for coupling the processing circuit 110 to the random access memory 120 through the PCB 100B. For example, the pitch X_Pitch2 may be equal to a predetermined value such as 0.6 mm, and the pitch Y_Pitch2 may be equal to a predetermined value such as 0.7 mm, but the present invention is not limited thereto. In some examples, the pitch X_Pitch2 and/or the pitch Y_Pitch2 may vary.

Some implementation details regarding pitch setting may be further described as follows. The method may use X_Pitch2=0.6 mm and Y_Pitch2=0.7 mm to implement the associated layout for LPDDR5 design. Regarding the pitch Y_Pitch2 in the Y direction, as the space between two vias (e.g., general via(s) and/or ground via(s)) should be sufficient for routing a signal line, if the diameter D_{drill} of the via drill is equal to 8 mils, the drill to copper clearance D_{clearance} is equal to 8 mils and the minimum line/trace width D_{trace} is equal to 3.5 mils, then the required minimum pitch Y_Pitch2_{Min} may be calculated as follows:

Y_Pitch2_{Min}=D_{drill}+(D_{clearance}*2)+D_{trace}=(8+(8*2)+3.5)mils=27.5 mils; where 1 mil=( 1/1000) inch, so Y_Pitch2_{Min}=0.6985 mm. In the case of selecting/reserving one significant digit, 0.6985˜=0.7, which means that the method may use 0.7 mm as the predetermined value for setting the pitch Y_Pitch2, but the present invention is not limited thereto. Regarding the pitch X_Pitch2 in the X direction, as the space between four adjacent SoC ball pads along any diagonal among the diagonals of the rectangle defined by the respective center points of the four adjacent SoC ball pads should be sufficient for putting a via, if the diameter Dpad of one SoC ball pad is equal to 0.3 mm, then the required length D_{diagonal} of the diagonal may be calculated as follows:

D_{diagonal}=D_{pad}+(D_{clearance}*2)+D_{drill}=0.3 mm+(8*3) mils=0.3 mm+24 mils; where 1 mil=( 1/1000) inch, so D_{diagonal}=0.9096 mm. Given that the diagonal divides this rectangle into two triangles, for any triangle among these two triangles, the required minimum pitch X_Pitch2_{Min} may be calculated according to Pythagorean theorem as follows: X_Pitch2_{Min}=((D_{diagonal}²−Y_Pitch2²))^{0.5}=((0.9096²−0.7²))^{0.5} mm ˜=0.581 mm.

In the case of selecting/reserving one significant digit, 0.581˜=0.6, which means that the method may use 0.6 mm as the predetermined value for setting the pitch X_Pitch2, but the present invention is not limited thereto. Taking the circuit structure 200 of the PCB 100B and the package 110P of the processing circuit 110 (or the SoC) as an example, as shown in FIG. 2 to FIG. 6, FIG. 7A and FIG. 7B, the LPDDR5 ball output on the left hand side of the SoC may be coupled to the multiple pads 102 (as well as the corresponding terminals of the LPDDR5/5X random access memory) through the associated connection lines toward/leading to the predetermined installation region 202, and may be implemented using X_Pitch2=0.6 mm and Y_Pitch2=0.7 mm.

Assuming that smaller vias are adopted, for example, D_{drill}=6 mils and D_{pad}=14 mils (or 0.3556 mm), when electronic devices are implemented in this manner, a common SoC ball pitch such as 0.65 mm may be used, but the PCB costs will increase. Regarding LPDDR5 signals, the present invention can use X_Pitch2=0.6 mm and Y_Pitch2=0.7 mm for designing the above-mentioned LPDDR5 ball output in order to achieve optimal configuration, but the present invention is not limited thereto. According to some embodiments, the predetermined value for setting the pitch X_Pitch2 and the predetermined value for setting the pitch Y_Pitch2 may vary. For example, the predetermined value for setting the pitch Y_Pitch2 may be any value in the interval [0.6985, 0.7] (in unit of mm), and the predetermined value for setting the pitch X_Pitch2 may be any value in the interval [0.581, 0.6] (in unit of mm). In another example, regarding the pitch Y_Pitch2 in the Y direction, if a smaller minimum line/trace width D_{trace} is used, especially if the minimum line/trace width D_{trace} is changed from 3.5 mils to 3.0 mils, then Y_Pitch2Min=0.6858 mm, which means that the predetermined value for setting the pitch Y_Pitch2 may be any value in the interval [0.6858, 0.7] (in unit of mm), and the range of multiple candidate values that may be selected as this predetermined value may be expanded from the interval [0.6985, 0.7] to the interval [0.6858, 0.7] (in unit of mm). In yet another example, regarding the pitch X_Pitch2 in the X direction, if smaller SoC ball pads are used, especially if the diameter Dpad of the SoC ball pads is changed from 0.3 mm to 0.25 mm, then X_Pitch2_{Min}=0.4989 mm, which means that the predetermined value for setting the pitch X_Pitch2 may be any value in the interval [0.4989, 0.6] (in unit of mm), and the range of multiple candidate values that may be selected as this predetermined value may be expanded from the interval [0.581, 0.6] to the interval [0.4989, 0.6] (in unit of mm). For brevity, similar descriptions for these embodiments are not repeated in detail here.

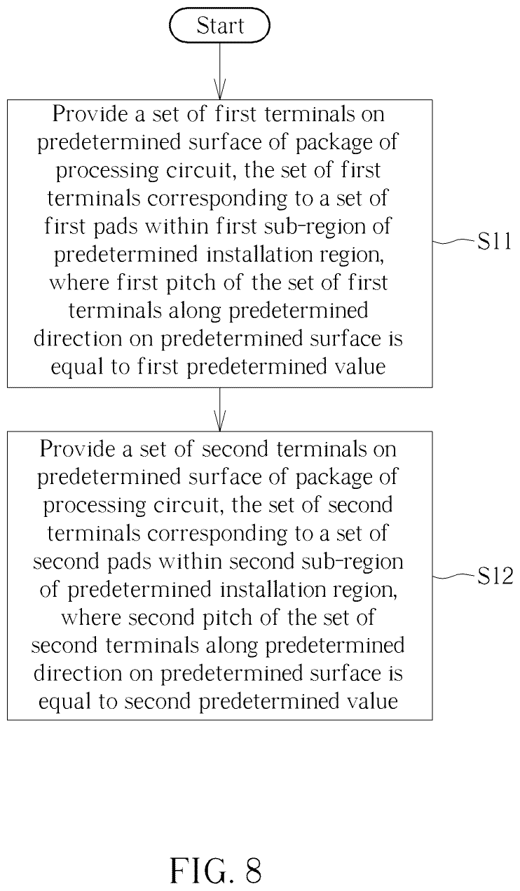

FIG. 8 illustrates a flowchart of the method according to an embodiment of the present invention. The processing circuit 110 (or the multiple terminals 111 in the terminal region 701 on the predetermined surface 110S of the package 110P) and the PCB 100B (or the multiple pads 101 in the predetermined installation region 201 thereon) may be implemented according to method.

In Step S11, provide a set of first terminals (e.g., the set of terminals 111_1) on the predetermined surface 110S of the package 110P of the processing circuit 110, the set of first terminals (e.g., the set of terminals 111_1) corresponding to a set of first pads (e.g., the set of pads 101_1) within a first sub-region (e.g., the sub-region 610) of the predetermined installation region 201, where a first pitch Pitch1 (e.g., the pitch X_Pitch1 or the pitch Y_Pitch1) of the set of first terminals such as the set of terminals 111_1 along a predetermined direction (e.g., the direction of the X-axis or the Y-axis) on the predetermined surface 110S is equal to a first predetermined value.

In Step S12, provide a set of second terminals (e.g., the set of terminals 111_2) on the predetermined surface 110S of the package 110P of the processing circuit 110, the set of second terminals (e.g., the set of terminals 111_2) corresponding to a set of second pads (e.g., the set of pads 101_2) within a second sub-region (e.g., the sub-region 620) of the predetermined installation region 201, where a second pitch Pitch2 (e.g., the pitch X_Pitch2 or the pitch Y_Pitch2) of the set of second terminals such as the set of terminals 111_2 along the predetermined direction (e.g., the direction of the X-axis or Y-axis) on the predetermined surface 110S is equal to a second predetermined value, and the second predetermined value is not equal to the first predetermined value.

For example, the second pitch Pitch2 (e.g., the pitch X_Pitch2 or the pitch Y_Pitch2) is different from the first pitch Pitch1 (e.g., the pitch X_Pitch1 or the pitch Y_Pitch1) to allow the layout space regarding at least one of a signal line and a via to be reserved between at least two adjacent second pads among the set of second pads (e.g., the set of pads 101_2), for coupling the processing circuit 110 to the random access memory 120 through the PCB 100B.

Based on the method, the PCB 100B may be arranged to install/mount the processing circuit 110 such as the SoC and the random access memory 120 such as an LPDDR 5 or above random access memory. The package 110P of the processing circuit 110 may comprise the multiple terminals 111 on the predetermined surface 110S, such as the set of terminals 111_1 positioned within the sub-region 710 of the terminal region 701 on the predetermined surface 110S that are arranged with the pitch X_Pitch1 along the direction of the X-axis and with the pitch Y_Pitch1 along the direction of the Y-axis, and the set of terminals 111_2 positioned within the sub-region 720 of the terminal region 701 on the predetermined surface 110S that are arranged with the pitch X_Pitch2 along the direction of the X-axis and with the pitch Y_Pitch2 along the direction of the Y-axis. In addition, the PCB 100B may comprise the multiple pads 101 on its top surface (e.g., the top surface of the top layer L1 within the above-mentioned five-layer circuit), such as the set of pads 101_1 positioned within the sub-region 610 of the predetermined installation region 201 on the top surface that are arranged with the pitch X_Pitch1 along the direction of the X-axis and with the pitch Y_Pitch1 along the direction of the Y-axis, and the set of pads 101_2 positioned within the sub-region 620 of the predetermined installation region 201 on the top surface that are arranged with the pitch X_Pitch2 along the direction of the X-axis and with the pitch Y_Pitch2 along the direction of the Y-axis. Additionally, the sub-region 710 of the terminal region 701 and the sub-region 610 of the predetermined installation region 201 correspond to each other, and the sub-region 720 of the terminal region 701 and the sub-region 620 of the predetermined installation region 201 correspond to each other.

In the 3D space corresponding to the X-axis, the Y-axis and the Z-axis that are orthogonal to each other, in a situation where the normal vector of the predetermined installation region 201 is parallel to the Z-axis and the processing circuit 110 and the random access memory 120 are arranged along the direction of the X-axis on the PCB 100B, the predetermined direction may represent the direction of any axis among the X-axis and the Y-axis. For example, when the predetermined direction represents the direction of the X axis, the first pitch Pitch1 may represent a first X pitch such as the pitch X_Pitch1, and the second pitch Pitch2 may represent a second X pitch such as the pitch X_Pitch2, where the second predetermined value may fall within the range of 0.4989 mm to 0.6 mm. In another example, when the predetermined direction represents the direction of the Y axis, the first pitch Pitch1 may represent a first Y pitch such as the pitch Y_Pitch1, and the second pitch Pitch2 may represent a second Y pitch such as the pitch Y_Pitch2, where the second predetermined value may fall within the range of 0.6858 mm to 0.7 mm. For brevity, similar descriptions for this embodiment are not repeated in detail here.

For better comprehension, the method may be illustrated with the working flow shown in FIG. 8. According to some embodiments, one or more steps may be added, deleted, or changed in the working flow shown in FIG. 8. For example, another first pitch Pitch1′ (e.g., the pitch Y_Pitch1 or the pitch X_Pitch1) of the set of first terminals such as the set of terminals 111_1 along another predetermined direction (e.g., the direction of the Y-axis or the X-axis) on the predetermined surface 110S is equal to a third predetermined value, and another second pitch Pitch2′ (e.g., the pitch Y_Pitch2 or the pitch X_Pitch2) of the set of second terminals such as the set of terminals 111_2 along the other predetermined direction (e.g., the direction of the Y-axis or the X-axis) on the predetermined surface 110S is equal to a fourth predetermined value, where the fourth predetermined value is not equal to the third predetermined value. When the predetermined direction represents the direction of the X axis and the other predetermined direction represents the direction of the Y axis, the first pitch Pitch1 may represent the first X pitch such as the pitch X_Pitch1, the second pitch Pitch2 may represent the second X pitch such as the pitch X_Pitch2, the other first pitch Pitch1′ may represent the first Y pitch such as the pitch Y_Pitch1, and the other second pitch Pitch2′ may represent the second Y pitch such as the pitch Y_Pitch2. In particular, the second predetermined value may fall within the range of 0.4989 mm to 0.6 mm, and the fourth predetermined value may fall within the range of 0.6858 mm to 0.7 mm. For brevity, similar descriptions for these embodiments are not repeated in detail here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of using optimized pitch for installing a processing circuit at a printed circuit board (PCB), the PCB having a predetermined installation region for installing the processing circuit, the method comprising:
providing a set of first terminals on a predetermined surface of a package of the processing circuit, the set of first terminals corresponding to a set of first pads within a first sub-region of the predetermined installation region, wherein a first pitch of the set of first terminals along a predetermined direction on the predetermined surface is equal to a first predetermined value; and
providing a set of second terminals on the predetermined surface of the package of the processing circuit, the set of second terminals corresponding to a set of second pads within a second sub-region of the predetermined installation region, wherein a second pitch of the set of second terminals along the predetermined direction on the predetermined surface is equal to a second predetermined value, and the second predetermined value is not equal to the first predetermined value.

2. The method of claim 1, wherein the predetermined direction represents a direction of an X-axis, the first pitch represents a first X pitch, and the second pitch represents a second X pitch; and the second predetermined value falls within a range of 0.4989 millimeters (mm) to 0.6 mm.

3. The method of claim 2, wherein another first pitch of the set of first terminals along another predetermined direction on the predetermined surface is equal to a third predetermined value, and another second pitch of the set of second terminals along the other predetermined direction on the predetermined surface is equal to a fourth predetermined value; the other predetermined direction represents a direction of a Y-axis, the other first pitch represents a first Y pitch, and the other second pitch represents a second Y pitch; and the fourth predetermined value falls within a range of 0.6858 mm to 0.7 mm.

4. The method of claim 1, wherein the predetermined direction represents a direction of a Y-axis, the first pitch represents a first Y pitch, and the second pitch represents a second Y pitch; and the second predetermined value falls within a range of 0.6858 millimeters (mm) to 0.7 mm.

5. The method of claim 1, wherein another first pitch of the set of first terminals along another predetermined direction on the predetermined surface is equal to a third predetermined value, and another second pitch of the set of second terminals along the other predetermined direction on the predetermined surface is equal to a fourth predetermined value, wherein the fourth predetermined value is not equal to the third predetermined value.

6. The method of claim 1, wherein the second pitch is different from the first pitch to allow a layout space regarding at least one of a signal line and a via to be reserved between at least two adjacent second pads among the set of second pads, for coupling the processing circuit to a random access memory through the PCB.

7. The method of claim 1, wherein the PCB is arranged to install the processing circuit and a low-power double data rate (LPDDR) 5 or above random access memory.

8. The method of claim 1, wherein the PCB is arranged to install the processing circuit and a random access memory; and in a three-dimensional (3D) space corresponding to an X-axis, a Y-axis and a Z-axis that are orthogonal to each other, in a situation where a normal vector of the predetermined installation region is parallel to the Z-axis and the processing circuit and the random access memory are arranged along a direction of the X-axis on the PCB, the predetermined direction represents a direction of any axis among the X-axis and the Y-axis.

9. A processing circuit whose package is implemented according to the method of claim 1, wherein the package of the processing circuit comprises:
the set of first terminals, positioned in a first sub-region of a terminal region on the predetermined surface, wherein the first sub-region of the terminal region and the first sub-region of the predetermined installation region correspond to each other; and
the set of second terminals, positioned in a second sub-region of the terminal region on the predetermined surface, wherein the second sub-region of the terminal region and the second sub-region of the predetermined installation region correspond to each other.

10. A printed circuit board (PCB) whose multiple pads are implemented according to the method of claim 1, wherein the multiple pads of the PCB comprise:
the set of first pads, positioned in the first sub-region of the predetermined installation region; and
the set of second pads, positioned in the second sub-region of the predetermined installation region.
